(19) United States
(12) Patent Application Publication
(10) Pub. No.: US 2026/0171852 A1
(43) Pub. Date: Jun. 18, 2026

(54) OPTICAL WIRELESS POWER TRANSMISSION USING LASER DIODES

(71) Applicant: Wi-Charge Ltd., Rehovot (IL)

(72) Inventors: Ori Mor, Tel Aviv (IL); Ortal Alpert, Ness Ziona (IL); Lior Golan, Ramat Gan (IL); Omer Nahmias, Aminadav (IL); Ilanit Shapir, Rehovot (IL)

(73) Assignee: Wi-Charge Ltd., Rehovot (IL)

(21) Appl. No.: 19/125,403

(22) PCT Filed: Oct. 29, 2023
(86) PCT No.: PCT/IL2023/051115

§ 371 Date: Apr. 29, 2025

(30) Foreign Application Priority Data
Oct. 29, 2022 (IL) 297760

(51) Int. Cl. H02J 50/30; H01S 5/02; H01S 5/065; H01S 5/068; H01S 5/10; H01S 5/11; H01S 5/20; H01S 5/323

(52) U.S. Cl. CPC H02J 50/30; H01S 5/0218; H01S 5/0651; H01S 5/06825; H01S 5/1039; H01S 5/11; H01S 5/2036; H01S 5/3235

(57) ABSTRACT

A system for transmitting laser power to a remote receiver, comprising a laser diode, an optical system for collimating and focusing the laser beam onto the receiver, and a scanning system for directing the beam towards the receiver. The beam has a wavelength of 1150-1550 nm, has a power of >300 mW, has an emitter width of between 15 and 250 μm, and is a spatial multimode beam, having >50% of its power in the TEM₀₀ mode, and <15% of its power in higher order TEMₙₘ modes having (n+m)>20. The lasing cavity has a Fresnel Number between 0.01 and 20, and a slow axis M² of <15, and a fast axis M² of <1.5, and a fast axis divergence of <60°. The collimated laser beam has a single lobe when imaged to a range of up to 10 meters.

### FIELD

The present invention relates to the field of laser-based wireless power transmission, for providing power to a remote receiver, and especially to the need for a power source that can provide a beam for ensuring efficient and safe transfer of the wireless power over the required distance to the remote receiver.

### BACKGROUND

There exist systems for the transmission of optical power to a remote location without the need for a physical wire connection. This need has become important in the last few decades, with the popularization of portable electronic devices operated by batteries, which need recharging periodically. Presently, the capacity of state of the art batteries and the typical battery use of a smart phone intensively used may be such that the battery may need charging more than once a day, such that the need for remote wireless battery recharging is important. Several prior art systems have been proposed for transmitting power safely to remote locations, which can be characterized as being at a distance significantly larger than the dimensions of the transmitting or receiving device. A typical configuration would be for the transmission of power to a receiver the size of a smart phone over a distance typical of a domestic room setting. The reception of the transmitted power is generally performed by use of a photovoltaic cell or cells, allowing transfer of optical power from a transmitted laser beam to mobile devices safely. The transmitted laser beam therefore needs to have a sufficiently high power to fulfill its intended function, but must provide that power level while maintaining a closely collimated beam which will transfer the great majority of its power, onto the photovoltaic cell, such that efficient transfer of the optical energy is performed without endangering the environment or persons along the transmission region, because of excessive beam divergence and leakage.

An advantageous power source for such laser power generation is a laser diode, as is used for many industrial, analytic and medical aspects of the use of laser power. Many of these applications using diode lasers require very different properties of the beam, and the laser diode industry has provided devices for these various needs. Thus, for instance, laser diodes for analytical spectroscopy or microscopy generally have low power levels, but should have a narrow line width wavelength emission, and a very low divergence beam, typically less than 2 mrad when collimated. On the other hand, a laser diode, or a laser diode bar, or an array of laser diodes, for use in an industrial process, such as for cutting or welding, should have as high a power as possible, while the beam divergence is generally far less critical. Laser beams for medical use, such as for ablation or as a laser scalpel, require well-focused beams but can be multi-mode, having comparatively high divergence from the complex mode structures.

In an attempt to increase the efficiency of laser diodes, and hence the power output as a function of input power, instead of lasers having symmetric, or what is termed in the art as “near-symmetric” structures, laser diodes having asymmetric structures have recently been developed. Some such asymmetric diode structures have been described in U.S. Pat. No. 8,798,109 to G. Erbert et al, for “High Efficiency Diode Laser” and in the article by L. W. Hallman et al, for “High Power 1.5 μm Pulsed Laser Diode with Asymmetric Waveguide and Active Layer near p-Cladding” published in IEEE Photonics Technology Letters, Vol. 31, No. 20, October 2019, on pages 1635-1638, and in the Article entitled “Efficient High Power Laser Diodes” by P. Crump, et al, published in IEEE J. of Selected Topics in Quantum Electronics, Vol 19, Issue 4, July-August 2013.

The disclosures of each of the publications mentioned in this section and in other sections of the specification, are hereby incorporated by reference, each in its entirety.

### SUMMARY

A laser beam for wireless transmission of optical power to a remote receiver is an application which involves a combination of two essentially contradictory characteristics. Firstly, a power level sufficient to provide the needs of the power receiver is required, which typically implies a power level that is, at the current state of laser diode technology, only available from multimode diode lasers, operated in such a way to emit a multimode beam. Secondly, the beam is required to be collimated to such an extent that the majority of its power impinges on the receiving element, which implies the generation of a beam from the laser diode, having a low order mode. Such a combination is thus generally considered to be a contradiction in properties of laser diodes, making it difficult to achieve the construction of an efficient laser power transmission system to remote receivers. Because of this difficulty, some prior art wireless optical power transmission systems are based on lasers other than diode lasers, or alternatively, if diode lasers are used, employ receivers with large aperture photovoltaic detectors, which removes the necessity to focus the beam into a small spot.

The requirements for laser projection, meaning the formation of a small laser-illuminated spot, having high power, at a distance from the projector, are complex. On the one hand the laser beam needs to have good optical quality, in order to be able to focus onto a small spot. Therefore, some prior art systems call for use of single spatial mode diodes, which are indeed suitable for low power applications but cannot be used for higher power applications, since single mode diodes are generally power limited. Currently, single mode diode lasers having more than 600 mW of output optical power are not available commercially. Other prior art systems use multimode diodes, but this limits the projection range at which the laser can form a small enough spot, since a multimode beam cannot be collimated well without significant power loss.

The current invention discloses an optical power transmission system having a laser diode which is suitable for projection applications where high power is needed, but without compromising the ability of the laser diode to project onto a small spot at a desired remote distance, such as in optical wireless power transmission applications.

In order to implement and operate such a projection system, the laser beam should have at least the following three characteristics. Alongside each beam property, there is stated the specific feature or structure required by the laser diode in order to achieve such a laser beam property.

Wavelength—The laser beam should have a wavelength of between 1150 nm and 1550 nm, to ensure eye safety, with no more than 2 mW of power emitted outside of that range. The wavelength emitted by the laser diode is dependent on the bandgap of the active gain medium used in the laser diode, hence the gain layer's bandgap should be selected to be in the range from approximately 0.8 eV to approximately 1.2 eV for the above mentioned beam wavelength range. (The higher bandgap 1.2 eV corresponds to a wavelength more energetic, i.e. lower than 1150 nm, since as the gain medium heats up as the diode lases, the bandgap tends to reduce somewhat.) Such a bandgap can be achieved by constructing the laser diode on a substrate of a III-V or II-VI semiconductor, having a gain layer made from any of:
a. A quantum dot structure,
b. A GaInAs composition,
c. A GaAsSb composition,
d. An InPAs composition,
e. An InAlAs composition, or
f. A quaternary material.

Beam Power—the beam output power should be at least 300 mW, in order to provide the level of electrical power, after conversion in the receiver, to charge the battery of a typical mobile phone, for instance, within a time acceptable to the user. Taking into account the efficiency of the laser diode itself, the input drive current to the diode should be at least 800 mA at an applied voltage of at least 0.8V, the value being determined by the gain medium used, and its I-V characteristic curve.

Beam Mode—As a preliminary comment, it is to be clarified that the terms “single mode” and “multimode” in the context of the present application, are used to describe a single spatial (or transverse) mode, and a multi-spatial (or transverse) mode, respectively, and not single or multi longitudinal modes. The laser diode may be a multimode device, to ensure a sufficiently high power level, but the design parameters of the laser diode should be such the emitted multimode beam would have a specific mode structure so that its output beam should have at least 50% of its power concentrated in the Hermitian-Gaussian TEM₀₀ mode, and less than 15% of its power in higher order TEMₙₘ modes, where the mode orders are such that (n+m) is greater than 20. Such design parameters are described in more detail below. As stated above, these mode characteristics are carefully selected to provide a beam compatible with the generally contradictory properties of a high output power, associated with a multimode beam, and good collimation properties, associated with a single mode beam.

These properties result from careful selection of the geometry, and especially the width of the gain layer of the laser diode. As will be shown hereinbelow, the cladding layers of the diode structure adjacent to the gain layer, are the layers which define the outer extent of the active cavity or resonator region, in the fast axis direction of the laser diode, and can be regarded as the radiation emitting height in the fast axis. The positively and negatively doped layers adjacent to the thin laser amplification layer, referred to herewith as the gain layer, has a refractive index n₁, while the cladding layers have a refractive index n₂, being lower than that of the gain layer. There are typically 2 such layers typically having the same refractive index n₂. If the indices are different, n₂ and n₃, the lower of the two should be used in making the calculations of the laser diode properties shown below.

In order to achieve from the diode, the mode distribution mentioned above, with the majority of power located in lower order modes, the Fresnel number, FN, of the cavity in the slow axis, which is the wide dimension of the gain region cross section, should be in the range given by the expression 0.01<FN<20. The FN is given by the expression w²/λL, where L is the overall length of the lasing cavity. In order to provide these values, the emitter width, w, should be in the range 15-250 micron.

Such a mode distribution will allow the M² value of the beam in the slow axis direction to be less than 15.

Because of the small height of the gain area, which is defined as the positively doped layer, the laser amplification layer and the negatively doped layer, the M² value of the fast axis should be less than 1.5, and the fast axis divergence should be less than 60°.

Such a selection of the M² value and of the mode structure, will allow the beam mode to have a single lobe when imaged at 10 m, and will allow the focused spot size r such a distance to reach an optimal size.

The spot size, r, created by the beam after focusing, should be in the range

$$20 h * tan ( \frac{6 * 1 {0}^{- 7}}{h} ) < r < \frac{10 W}{2000000 * {h}^{2}} \qquad ( 1 )$$

where:
h is the height of the gain layer measured in meters,
w is the width of the gain layer measured in meters,
r is the effective radius of a spot containing 95% of the power of the beam as projected, also measured in meters, and
the angle whose tangent is given, is measured in radians.

It is to be understood that, since in many of such systems, the spot will not be a circle, the term “effective radius”, throughout this disclosure, relates to a measurement being half of a mean lateral outer dimension of the illumination spot containing 95% of the spot power.

A brief summary of the salient features of an exemplary implementation of the claimed systems of the present disclosure, with brief explanations where necessary of the motives for each feature, can be expressed as:

A system for transmitting laser power from a transmitter to a remote receiver, comprising:
a laser diode source comprising a gain medium, and supplied with current from a laser driver, an optical system for collimating the laser beam emitted from the laser diode source, to produce a spot of illumination on the remote receiver, and
a scanning system for directing the collimated laser beam towards the aperture of a photovoltaic cell on the remote receiver, wherein:
(i) the laser diode emits a beam at a wavelength λ of between 1150 nm and 1550 nm so that it is invisible to the human eye and provides greater safety due to water absorption in the longer wavelengths of that range,
(ii) the laser beam has a power of at least 300 mW so that it is sufficiently powerful to provide the desired power to the client device,
(iii) the laser diode source has an emitter width w of between 15 and 250 μm which enables the achievement of the laser beam as a spatial multimode beam, having at least 50% of its power concentrated in the Hermite-Gaussian TEM₀₀ mode, and less than 15% of its power in higher order TEMₙₘ modes whose orders are such that (n+m) is greater than 20, thereby facilitating the generation of a beam having a suitable M² value,
(iv) the laser diode source has a lasing cavity having dimensions such that the laser beam emitted therefrom has a fast axis and a slow axis, and
(v) the lasing cavity of the laser diode has a Fresnel Number in the slow axis, w²/λL, of between 0.01 and 20, where L is the length of the laser cavity, the above characteristics being such that the resulting beam would have:
(vi) an M² value in the direction of the slow axis less than 15,
(vii) an M² value in the direction of the fast axis less than 1.5, and the divergence of the laser beam in the direction of the fast axis being less than 60°,
(viii) a mode of the collimated laser beam, when imaged by the optical system at a distance of 10 m, having a single lobe, and
(ix) a spot size r of the laser beam, thereby created, being given by the expression:

$$20 h * tan ( \frac{6 * {10}^{- 7}}{h} ) < r < \frac{10 w}{2000000 * {h}^{2}}$$

where h is the height of p- and n-doped layers of the laser source gain medium, measured in meters,
w is the width of the gain medium, measured in meters,
r is an effective radius, and
the tan function is in radians.

There is thus provided in accordance with an exemplary implementation of the devices described in this disclosure, a system for transmitting laser power from a transmitter to a remote receiver, the system comprising:
a laser diode emitting a laser beam for optical wireless power transmission, the laser diode comprising:
(i) a first cladding layer having a first refractive index, and a second cladding layer having a second refractive index, between which there lies an emitting region comprising:
(ii) a positively doped layer having a third refractive index, and a negatively doped layer having a fourth refractive index, each of the third and the fourth refractive indices being larger than either of the first and second refractive indices, and
(iii) a gain medium layer deposited between the positively doped layer and the negatively doped layer, and having an energy bandgap of between 0.8 eV to 1.2 eV,
   wherein the width w, in meters, of the emitting region is within the range:

$$\frac{5 * {10}^{- 27}}{E * {n}_{2}} > \frac{5 * {10}^{- 27}}{E * {n}_{1}} > w > \frac{5 * {10}^{- 28}}{E * {n}_{2}} > \frac{5 * {10}^{- 28}}{E * {n}_{1}}$$

where E is the bandgap of the gain layer measured in Joules, n₁ is the average refractive index of the doped layers, and n₂ is the average refractive index of the cladding layers, and wherein:
(a) the upper limit of w is selected to ensure that in the slow axis, the beam has a spatial multimode form of a required quality, by having at least a first predetermined percentage of its power concentrated in the Hermitian-Gaussian TEM₀₀ mode, and no more than a second predetermined percentage of its power in higher order TEMₙₘ modes, having (n+m) greater than a preset number, and
(b) the lower limit of w is selected to ensure that in the slow axis, the beam has sufficient combination of higher order modes so that it produces at least a required level of laser beam output power.

In such a laser diode, the first and second refractive indices may have essentially the same value, and the third and fourth refractive indices may have essentially the same value.

Furthermore, according to a further implementation of such laser diodes, the first predetermined percentage should be 50%, the second predetermined percentage should be 15%, the preset number should be 20, and the desired level of laser beam output power should be 300 mW. In the last case, the level of laser beam power having a wavelength outside of a range from 1150 nm to 1550 nm should be less than 2 mW.

In any of the previously described laser diodes, the cavity may have such a length L that for the range of w of claim 1, the Fresnel Number in the slow axis, w²/λL, should be between 0.01 and 20, where L is measured in meters.

Furthermore, in any of the previously described laser diodes, the laser beam may have:
(i) an M² value in the direction of the slow axis of less than 15, and
(ii) an M² value in the direction of the fast axis of less than 1.5, and a divergence of the laser beam in the direction of the fast axis of less than 60°.

Additionally, according to yet another implementation of such laser diodes,
(i) the mode of the collimated laser beam is such that when imaged by an appropriate optical system to a distance of 10 m., the beam has a single lobe, and
(ii) the effective radius r of the focused laser beam thereby created at the 10 m. distance, is given by the expression:

$$20 h * tan ( \frac{6 * {10}^{- 7}}{h} ) < r < \frac{10 w}{2000000 * {h}^{2}}$$

where h is the height of the laser emitter, measured in meters,
w is the width of the emitting region, measured in meters,
r is the effective spot radius, measured in meters, and
the tan function is in radians.

In any of the above described implementations, the effective radius r of the focused laser beam should include 95% of the laser beam power.

The laser gain medium layer of the above-described laser diodes may comprise any of:
(i) a quantum dot gain layer.
(ii) a GaInAs composition
(iii) a GaAsSb composition
(iv) an InPAs composition
(v) an AlAs composition or
(vi) a quaternary material.

Finally, in any of the previously described laser diodes, the cladding and doped diode layers may have a symmetrical or a near-symmetrical structure relative to the gain medium layer.

There is further provided in accordance with yet another exemplary implementation of the devices described in this disclosure, a system for transmitting laser power from a transmitter to a remote receiver, the system comprising:
(i) a laser diode source comprising a gain medium sandwiched between p- and n-doped layers, and supplied with current from a laser driver,
(ii) an optical system for collimating the laser beam emitted from the laser diode source, to produce a spot of illumination on the remote receiver, and
(iii) a scanning system for directing the collimated laser beam towards the aperture of a photovoltaic cell on the remote receiver, wherein:
(a) the gain medium of the laser diode is selected so that the laser diode emits a beam at a wavelength λ of between 1150 nm and 1550 nm,
(b) the current supplied by the laser driver to the gain medium is selected such that laser beam has a power of at least 300 mW, and
(c) the laser diode source has an emitter width w of between 15 and 250 μm, such that: the laser beam is a spatial multimode beam, having at least 50% of its power concentrated in
the Hermitian-Gaussian TEM₀₀ mode, and less than 15% of its power in higher order TEMₙₘ modes having (n+m) is greater than 20, and
the laser diode gain medium length is selected such that the laser diode has a Fresnel Number in a slow axis, w²/λL, of between 0.01 and 20, where L is the length of the laser cavity, yielding a beam having:
   an M² value in the direction of the slow axis of less than 15,
   an M² value in the direction of a fast axis of less than 1.5,
   a divergence of the laser beam in the direction of the fast axis of less than 60°,
   a single lobed mode of the collimated laser beam, when imaged by the optical system to a distance of 10 m, and
   a consequentially focused spot of the laser beam, given by the expression:

$$20 h * tan ( \frac{6 * {10}^{- 7}}{h} ) < r < \frac{10 w}{2000000 * {h}^{2}}$$

where h is the combined height of p- and n-doped layers and the gain medium, measured in meters,
w is the width of the gain medium, measured in meters,
r is an effective radius of the focused spot, and
the tan function is in radians.

In such a system, the bandgap of the gain medium of the laser diode should lie within the range of 0.8 eV to 1.2 eV. Additionally, such laser diodes may be constructed on a substrate of a III-V or II-VI semiconductor. Also, the gain medium layer may comprise any of a quantum dot structure, a GaInAs composition, a GaAsSb composition, an InPAs composition, an InAlAs composition, or a quaternary material.

Furthermore, in such systems, the focused spot size may have an effective radius r which includes 95% of the power of the beam. Additionally, the power of the laser diode emitted at wavelengths outside of the range between 1150 nm and 1550 nm, should not exceed 2 mW.

Finally, in such systems, the gain medium may be disposed between an n-doped layer and a p-doped layer, having a mean refractive index of n₁, and which are themselves disposed between cladding layers having a refractive index of n₂. In such a system, the width w of the gain medium should be within the ranges given by the expression:

$$\frac{5 * {10}^{- 27}}{E * {n}_{2}} > \frac{5 * {10}^{- 27}}{E * {n}_{1}} > w > \frac{5 * {10}^{- 28}}{E * {n}_{2}} > \frac{5 * {10}^{- 28}}{E * {n}_{1}}$$

where E is the bandgap of the gain medium layer measured in Joules,
n₁ is the mean refractive index of the doped layers, and
n₂ is the mean refractive index of the cladding layers.

According to yet more exemplary implementations of the above-described systems for transmitting laser power from a transmitter to a remote receiver, the electrical connections for providing current from the laser driver to the laser diode should be insulated connections adapted to prevent the likelihood of an inadvertent electrical connection to the laser diode, thereby increasing the safety of the system.

In such systems, the electrical connections for providing current from the laser driver to the laser diode should have at least one gated switch for controlling the flow of current through each of the electrical connections. These gated switches should be activated by a gate driver having an operating voltage higher than the operating voltage of other electronic circuits of the system providing control functions to the system. The gate driver may be configured to hold each of the gated switches in its conducting state, when the gate driver is instructed to activate the gate. In such a case, a fall of the operating voltage of the gate driver, to a level below the operating voltage of other electronic circuits of the system providing control functions to the system, causes the gate switches to revert to a non-conducting state. This non-conducting state thus isolates the laser diode from any source of current, even if arising from an inadvertent electrical connection to the laser diode.

### BRIEF DESCRIPTION OF THE DRAWINGS

The present invention will be understood and appreciated more fully from the following detailed description, taken in conjunction with the drawings in which:

FIG. 1 illustrates schematically an exemplary laser power transmission system as describe din this disclosure, for providing optical power to a remote receiver;

FIG. 2 shows the first Hermitian-Gaussian beam modes TEMₘₙ, and their relative spatial extent;

FIG. 3 shows schematically a schematic isometric view of a laser diode structure according to an exemplary implementation of the present disclosure;

FIG. 4 is a view from the top of the diode laser of FIG. 3; and

FIG. 5 shows schematically a block diagram of the main features of a powering scheme for the laser diode, providing a high level of operational safety even in the event of an inadvertent electrical connection to the laser diode.

### DETAILED DESCRIPTION

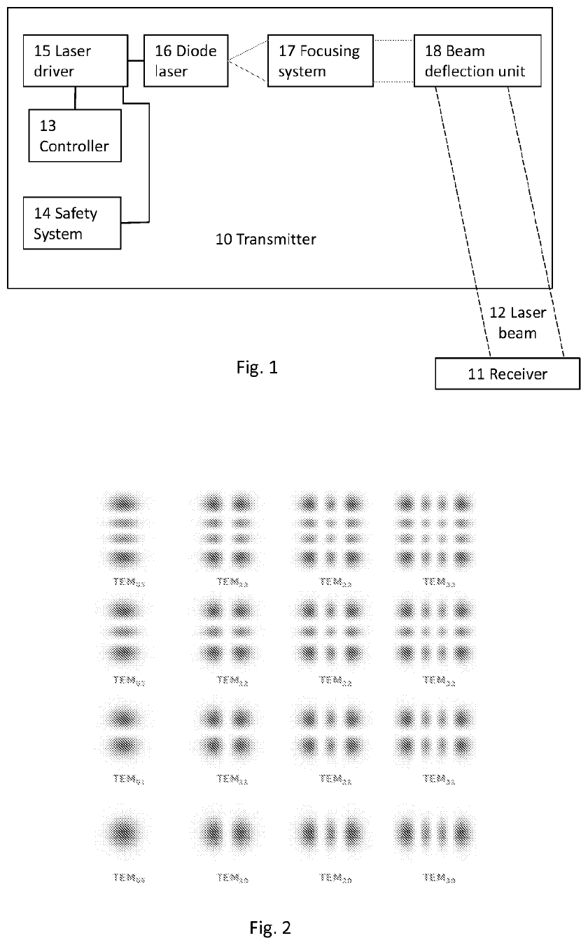

Reference is first made to FIG. 1, which illustrates schematically a laser power transmission system of the type used in the present disclosure, for providing power to a remote receiver. The transmitter 10 includes the laser source, advantageously a laser diode 16, and the necessary elements for controlling and directing the emitted laser beam 12. The transmitter also incorporates the laser driver 15, which provides the electrical power for the laser diode 16, a controller 13, which is operative to maintain the laser operating in the desired and require manner, and a safety system 14, which ensures that the laser beam transmission is being executed without generating hazards to the environment in which the transmission system is operating or to persons therein. The laser beam 12 emitted from the diode laser 16 diverges substantially, by up to 60° along the fast axis, and by up to 30° along the slow axis, though the typical slow axis divergence will be significantly less than that, even only 10°. The beam therefore has to undergo collimation by focusing system 17, which forms a focal point or a virtual focal point of the beam at a distance from the transmitter, typically at least 200 times the diameter of the focusing lens. The beam is then directed as a collimated, or, since perfect collimation is impossible, a nearly collimated beam 12, by the beam deflection unit 18 along the correct path towards its target receiver 11, where it impinges on a photovoltaic cell for conversion into electrical power. The methods described hereinbelow show how the system can be constructed with a laser diode 16 having a combination of characteristics such that the laser beam 12 reaches its target in a sufficiently focused state that it transfers the great majority of its power into the photovoltaic cell on the receiver 11, while at the same time, maintaining the power level required by the receiver to fulfil its intended function.

Laser diodes are generally categorized into single spatial mode laser diodes, and multimode laser diodes. Single mode diodes generally provide good beam quality while multi spatial mode laser diodes provide poorer beam quality. However single mode diodes are more power limited and hence cannot be used in projection applications such as for the wireless power supply applications described in this disclosure.

Throughout this document the shortened terms “single mode” and “multi-mode” refer to the single spatial (or transverse) mode and multiple spatial (or transverse) mode outputs, and not to single/multi longitudinal modes of the laser resonator, which are different terms relating to the change in beam cross section along the laser resonator, and largely irrelevant to the current application. Furthermore, throughout this disclosure, the term TEM mode generally refers to the Hermitian-Gaussian modes, although Laguerre modes may be referred to in some cases.

In general, the beam quality of single mode lasers is nearly perfect, in that they emit a nearly pure Gaussian beam, also known as the TEM₀₀ mode, which can readily be collimated or focused into a diffraction limited spot. Single mode lasers have an M² value close to 1, where a laser with an M² value of less than 1.2 would generally be considered to be a single mode laser. For such a single mode laser, almost all of the emitted power can be collected in the central Gaussian lobe of a collimated beam at optical infinity and can be focused into a diffraction limited spot, regardless of the dimensions of the emitter aperture of the laser.

Multimode lasers, on the other hand, support many spatial modes, designated TEMₘₙ modes, and have poorer beam quality. The output of a multimode laser cannot thus be collimated without a significant loss in power. Multimode lasers support many TEMₘₙ modes, where the value of the M² factor is given by (2n+1) in the x direction, and (2m+1) in the y direction. Consequently, even the low order TEM₀₁ mode has an M² value of 3 in the Y direction, while the TEM₀₅ has an M² value of 11 in the Y direction. Since the M² value of the beam is directly proportional to the ability to collimate and/or focus the beam, multimode beams from regular multimode lasers cannot be collimated or focused to a diffraction limited spot without a significant loss of power, caused by the loss of those parts of the mode which form the outer lobes of the beam.

Since it is inefficient and typically unsafe to project multimode beams over long distances, due to the inherent power loss out of the beam, when laser diodes are used as the source in an optical power transmission application, only single mode diode lasers have been generally used, and available power is therefore limited, as single mode diode lasers are power limited.

It should be noted that because of the ratio of cavity dimensions of diode lasers, their beams may have different M² value in different directions. Single mode diode laser beams typically have an M² value close to 1 in the “fast axis”, which is the narrow axis of the diode laser cavity, and an M² value close to 1 in the “slow axis”, which is the broader axis of the diode laser cavity, while multimode diode lasers have an M² significantly greater than 1.2, and typically around 10 or more in the “slow axis”.

Reference is now made to FIG. 2, which shows a set of images of the first Hermitian-Gaussian beam modes TEMₘₙ, and their relative extent, as is known in the art. The extended spatial extent of the different modes, other than the TEM₀₀ fundamental mode, is clear from the mode shapes shown in FIG. 2, and the inability to obtain a compact focused spot using the higher mode beams is thus apparent.

Laser beams emitted from single mode diodes generally comprise TEM₀₀ Hermitian-Gaussian modes only. In some cases the mode may be slightly distorted by diffraction from the edges of various apertures in the laser, such as the emitter, but as long as the M² value of the beam in both transverse directions is less than 1.3, and more preferably less than 1.2, the laser is still generally considered a single mode laser. Currently single mode diode lasers at the required wavelengths suitable for laser power transmission, are limited in power level to below 300 mW which limits their usability in projection applications.

Multimode diode lasers, on the other hand, emit beams containing a mixture of many modes, typically a variable mixture of many TEM modes such as TEM_{00, 01, 02, 03, 04, 05, 06 . . . 020}

A single mode beam can be focused to its diffraction limit, or nearly to its diffraction limit. Thus, for example, and as can be readily derived from optical design principles, a single mode beam emitted from a laser emitter of any size, and having a wavelength of 1μ, focused by an optical system having a numerical aperture of 0.01 would form a spot of ˜122 micron at its optimally focused distance. The projected spot size would not change based on the focal length of the lens used; only the numerical aperture of the converging beam influences spot size. These conclusions would obviously be true only for a perfect lens, without any aberrations, and a similarly perfect laser and intermediate medium.

Higher order modes, on the other hand, have an M² value of (2n+1) and cannot be focused down to the diffraction limit. Typically, a multimode beam can only form an image which is roughly the size of the emitter times the magnification of the focusing optical system. Thus, a typical multimode beam emitted from a 500 μm×1 μm emitter, focused by an f=10 mm focal length lens placed 10.1 mm from the emitter, would form a minimal spot at a distance of 10m. The magnification of that system is approximately 1:1000, and hence the length of the image formed at the 10 m distance would be roughly half a meter. The beam would be diffraction limited in the other dimension, such that the focused “spot” would be a thin long line. Since such a long line could not be absorbed by a conventionally shaped and sized photovoltaic cell, such a diode laser would not be suitable for use in long range projection applications.

In order to form a spot smaller than 1 cm from that multimode diode, the system magnification should be 20 or less and the lens would have to be positioned 50 cm. from the emitter. Such a system, even if complex optics were used instead of a single lens, would make the transmitter large and expensive, beyond acceptable limits for most applications.

Referring back now to the system shown in FIG. 1, laser diode 16 emits an expanding beam of light, the divergence angle of the emitted light being dependent mainly on the thickness of the p and n doped layers, including the thin gain medium layer, the thinner this combination of layers, the greater the divergence in the fast axis direction. Hence, in order to be able to successfully focus the light, while transmitting it with a small enough aperture to allow a reasonably sized device, the optical surface of focusing system 17 facing laser diode 16 should be placed at a distance d from the diode beam emitting surface, which lies, as can be shown from basic optical design principles, between the following two limits:

$$\frac{0.05}{tan ( \frac{6 * {10}^{- 7}}{h} )} < d < 2000000 * {h}^{2} \qquad ( 2 )$$

where d is the distance of the lens from the emitter aperture of the diode, measured in meters;
tan is the tangent function, the angle being measured in radians;
and h is the thickness (height) of the combined p and n doped layers and the gain layer between them, measured in meters.

This forms a spot at the receiver, in which 95% of the power is contained in a circle of radius r measured in meters, given by the range:

$$20 h * tan ( \frac{6 * {10}^{- 7}}{h} ) < r < \frac{10 w}{2000000 * {h}^{2}} \qquad ( 3 )$$

where h is the height (thickness) of the combined p and n doped layers, measured in meters, w is the emitter width of the gain layer, measured in meters, and the tan function is given in radians.

A laser diode with a larger emission width w, would form a spot too large for simple projection applications, and if h were reduced, the resulting device would need to be larger and more expensive as the beam's fast axis would diverge rapidly, requiring a very large lens for effective collimation, the lens being positioned at a very close distance to the diode. This would require tolerances on placement and structure, difficult to achieve. This is because, as seen previously, the distance between the diode and the lens is set by the required magnification necessary to allow for a small enough spot to be formed on the photovoltaic cell-moving the lens closer to the diode makes the spot size larger. Additionally, the diameter of the lens would be determined by the fast axis divergence on its way towards the lens. Hence choosing a value of h outside the above-desired range would result in a larger device, as the lens diameter would need to be very large in order to encompass a significant portion of the light emitted by the laser diode and to collimate it, or focus it at the desired range.

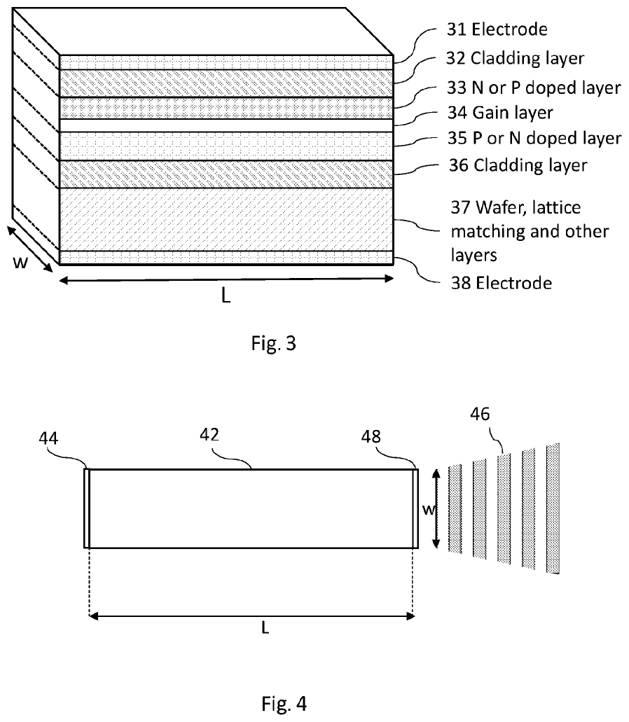

Reference is now made to FIG. 3, which shows schematically an schematic isometric view of the semiconductor layer structure of the laser diode, according to an exemplary implementation of the present disclosure. The view is from a point perpendicular to the surface of the wafer and perpendicular to the beam emission direction. The laser diode for this beam projection application is advantageously either a III-V or a II-VI semiconductor diode. The general structure of the diode comprises layers grown on a semiconductor wafer, of which there are typically many layers, but only some of which provide the resonator and the gain for the laser.

The layers providing the resonator and the gain for the laser typically comprise a pair of external cladding layers, with p and n doped layers internal to the cladding layers, and a gain-producing quantum well layer 34 located between the doped layers. The structure made of a gain layer surrounded by p and n doped layers may be repeated several times.

On the top and on the bottom of the diode are the anode and the cathode electrodes 31, 38, for powering the diode from the laser driver 15. The wafer is typically a GaAs, Ge, Si, InP or another common semiconductor wafer. Describing the structure from the lower electrode 38 and wafer 37, with the terms “up” and “down”, and “on top of” and “beneath” being as related only to what is shown graphically in the drawing of FIG. 3, a number of lattice matching layers 37 may be grown immediately on top of the wafer, below the diode structure itself, followed by a low index cladding layer 36. On top of the first cladding layer 36, a doped layer 35, either p-doped or n-doped, is grown, this layer having a refractive index which is larger than the refractive index of the first cladding layer 36, thereby defining the waveguide height.

A thin gain layer 34, generally having an even higher refractive index, is grown on the first doped layer 35. Typically, the thickness of the gain layer 34 is smaller than a single wavelength of the laser light. The gain layer 34 has a bandgap of between approximately 0.75 to 1.2 eV, and when powered up by the electrodes 31, 38, provides gain at the lasing wavelength. The gain medium, or quantum well composition may be any of:
1. Quantum dot;
2. GaInAs composition;
3. GaAsSb composition;
4. InPAs composition;
5. InAlAs composition; or
6. Quaternary material.

On top of the gain layer 34, a second doped layer 33, with the opposite doping to that of the first doped layer 35, is grown. Both the p and the n doped layers typically have a similar refractive index. The total height of the two doped layers and the thin gain layer 34 between them, which together define what is known as the height h of the laser resonator, determines, inter alia, the divergence of the fast axis of the laser diode. A second upper cladding layer 32, having a lower refractive index than that of the gain layer and doped layers, is deposited on top of the second doped layer 33.

The diode structure shown in FIG. 3 is that of what is known as a symmetric or nearly symmetric diode structure, in which the fundamental resonance mode is centered essentially symmetrically and centrally on the combined doped layers and gain medium layer waveguide structure contained between the outer cladding layers. Such diode structures generally provide beams with the cleanest output modes.

As mentioned previously, in an attempt to increase the efficiency, and hence the power output of the laser diode as a function of input power, laser diodes having asymmetric waveguide structures, have been developed, in which the active layer is purposely positioned very close to the cladding layer at the p-doped layer, in order to reduce current-induced non-uniform carrier accumulation on the p side of the waveguide structure, and the associated carrier losses. The cladding layer on this p-doped side of the diode waveguide is itself highly p-doped in order to reduce the series resistance thereof. All these features contribute to reducing the losses in the laser diode, thereby enabling higher output powers and efficiencies. However, such asymmetric diode structures are generally accompanied by a reduction in the purity of the output modes of the laser diode resonator. Additionally, multiple quantum well diode structures have been used to increase the power outputs, and these structural features are also generally accompanied by a reduction in the purity of the output modes of the laser diode resonator. Both of these methods of increasing the power output of the diode may be also tailored for use with the currently described laser diodes, but the results may still be considered to be less desirable for providing the desired beam collimation.

Reference is now made to FIG. 4, which is a view of the diode laser of FIG. 3, from the top, i.e. from above the outermost electrode 31 (or 38). FIG. 4 shows the top electrode 42 at the outer surface of the device. Although the top electrode 42 is shown in FIG. 4 covering the whole width of the diode structure, it could be slightly narrower than the entire wafer width. The current flowing through the diode between the electrodes creates population inversion in the part of the gain layer through which current flows, as well as small signal gain, and, during lasing operation, also saturated gain. A laser beam is formed between the back mirror 44, through the gain medium and towards the output coupler 48. Some of that beam is reflected back into the cavity resonator, while the other part is transmitted outside the laser as the output beam 46.

The resonator length L, typically within the range of 0.5 to 10 mm, is typically the distance between the back mirror 44 and the output coupler 48, while the width w is determined by the limiting aperture of the resonator. This would be either the width of the gain region or the width of the output coupler.

The emitter width, w, for the exemplary laser diodes of the present disclosure, should preferably be within the range of 15 to 250 μm.

The slow axis is that of the cavity width w, and the fast axis is that of the thickness (height) h of the gain medium with its two associated doped layers.

The Cavity Fresnel Number FN in the slow axis, w²/λL, should be within the range given by:

$$0.01 < FN < 20 \qquad ( 4 )$$

This will ensure that limited higher order modes are developed to allow the generation of higher power by the diode, while still suppressing very high order modes which limit focusability and safety. These low values of Fresnel numbers prioritize low order spatial modes but do not limit the diode to single mode operation.

The width w should be adjusted to be within the ranges:

$$\frac{5 * {10}^{- 27}}{E * {n}_{2}} > \frac{5 * {10}^{- 27}}{E * {n}_{1}} > w > \frac{5 * {10}^{- 28}}{E * {n}_{2}} > \frac{5 * {10}^{- 28}}{E * {n}_{1}} \qquad ( 5 )$$

where E is the bandgap of the gain layer measured in Joules and n₁ and n₂ are the refractive indices of the doped layers and the confinement or cladding layers, respectively.

For a diode of reasonable length, typically less than a few millimeters, such as are needed to achieve high yield and low cost, the above Fresnel numbers can be achieved with widths w of the order of 20 to 100 microns.

If the emitter width w is wider than the range given in expression (5), the diode will not be capable of being focused at the desired distance as too many high order modes would be created, and the spot will be too large for the projection application. If the emitter width w is too narrow, the diode will not have enough optical power, as an insufficient number of modes would be created to provide the power required in many power projection applications.

A laser diode cavity/resonator structure having the above defined width and Fresnel numbers ensures that the emitted beam would be of satisfactory optical quality. Specifically, such a beam should have the following advantageous qualities:

It would form a single lobe when focused using the above described optical system, at the desired distance from the emitter, allowing it to be focused onto a small receiver.

The lasing wavelength would be between 1150 and 1550 nm, advantageously providing eye safety and invisibility. More preferably, the lasing wavelength should be between 1200 and 1450 nm.

This beam would be a restricted multimode laser beam, especially in the “slow axis” (the direction of w), though single mode emissions should be obtained when the current through the diode is low.

The resulting beam from selecting the above parameters would be a beam which will be composed of at least 50% TEM₀₀ Hermitian-Gaussian mode, and have less than 15% of all Hermitian-Gaussian modes TEMₘₙ with m>0 and n>20. These limitations are necessary to achieve the desired ability to focus the beam into a small lobe at the range extent required, and to provide, at the same time, sufficient power to perform the required task.

Because of the chosen value of the width w and of the resonator Fresnel number, the beam will have a slow axis (w direction) spatial mode that is not TEM₀₀, but should still have an M² value of less than 6. Such a beam would be comprised of many TEMₘₙ modes, mixed in a combination, but ensuring that the ensuing M² value is less than 6. Each pure TEM mode has an M² value of 2m+1 or 2n+1, and the above combination of TEMₘₙ modes yields an overall M² value dependent on the percentages of the component higher modes in the output beam, and the M² value of each component mode of the beam. The M² value can be readily measured experimentally, using standard monitors for that purpose.

Because of the chosen value of the cavity height h, the fast axis divergence is less than 60 degrees. Furthermore, the fast axis (h direction) will have a spatial mode that has an M² of less than 1.4. Unlike a true single mode diode laser, the distance between the waist of the fast axis (on the emitter) and the waist of the slow axis (inside the diode) is less than 1 mm but always more than zero.

Such a laser diode would operate at a voltage V >0.8 volt and be capable of emitting >300 mW of light when supplied with at least 800 mA of current, and usually up to a few amperes.

The bandgap changes as a function of junction temperature and of current, as a result the Fresnel number, wavelength and diode characteristics would also change, such that the control unit should monitor the diode temperature, and be programmed to maintain the lasing stability of the beam.

At threshold current, the diode produces a single mode beam which would be focused into a very small diffraction limited spot (but low power), when current increases the power increases, the bandgap, and sometimes the Fresnel number changes, and the beam becomes similar to the beam described above. It is important to characterize the beam at its working current, but also at 25% above and below its working current and at two times the threshold current.

When focused by a lens positioned at a distance d from the emitter of the diode, where d is measured in meters, and is within the range:

$$\frac{0.05}{tan ( \frac{6 * {10}^{- 7}}{h} )} < d < 2000000 * {h}^{2} \qquad ( 6 )$$

where the angle of the tan function is measured in radians, and
h being the height of the p and n doped layers, measured in meters,
the diode is expected to produce a single lobe, when focused at a distance with a numerical aperture of 0.01, the lobe having a radius containing 95% of the power, limited to a radius r measured in meters, given by the range:

$$20 h * tan ( \frac{6 * {10}^{- 7}}{h} ) < r < \frac{10 w}{2000000 * {h}^{2}} \qquad ( 7 )$$

where h is the height of the p and n doped layers, measured in meters,
w is the width of the gain layer, measured in meters, and
the tan function is in radians.

A wider diode cavity would form a spot too large for such projection applications, and if h were to be reduced, would make the resulting device bigger and more costly. The beam should contain at least 50% of its power in the TEM₀₀, and less than 15% of its power in higher order TEMₙₘ modes, whose orders are such that (n+m) is greater than 20. This value should work for diode currents of between 2 and 4 times the threshold current, as well as for the regular level of working current.

The laser diodes described hereinabove provide efficient and safe laser beam transmission to the receiver power detector. However, the system must also include safety features that will not only enable the beam to be concentrated on the receiver photovoltaic cell, but will also warn of any situation where the beam may impinge on another body, which could be indicative of a laser hazard, and which should mandate cessation of the diode emission. The presently described system incorporates a number of features which ensure that in such a possibility, the system is provided with protection that will prevent unintended laser diode emission under such circumstances in which physical short circuits, or electronically virtual short circuits enable an operating current to pass through the laser diode. Such protective features are described in PCT Application PCT/IL2022/051040, for “A System for Location and Charging of Wireless Receivers”, commonly owned by the present applicant, and herewith incorporated by reference in its entirety in the present application. The main feature of these additional safety systems are (i) improved physical electrical insulation of the laser diode power leads, (ii) independently controlled switches in the anode and cathode leads of the laser diode, and (iii) activation of the system by a two-level power supply voltage arrangement.

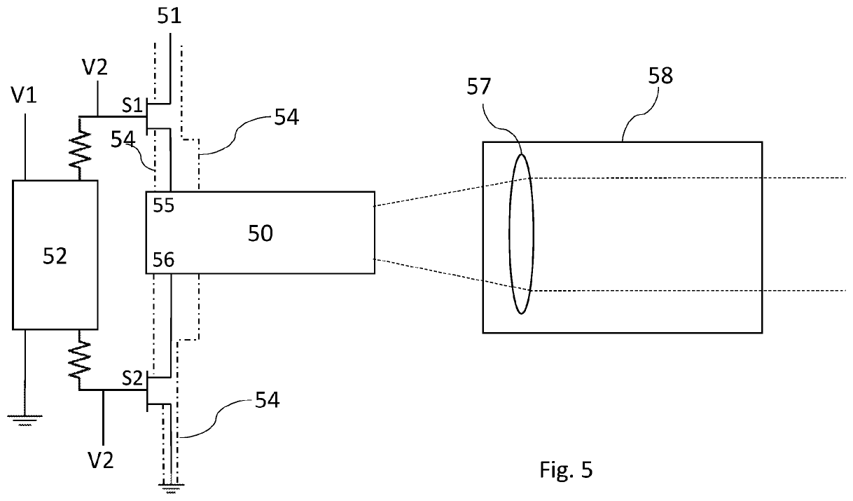

Reference is now made to FIG. 5, which shows schematically a block diagram of the main features of this powering scheme for the laser diode. The laser diode 50 is powered by a laser diode power supply 51, which receives its drive instructions from the system main controller 52. This main controller 52 is programmed to cause the laser diode to turn on and off and to adjust its power level during conventional operation of the system, using the laser diode power supply 51, providing a level of safety from laser hazards. The diode power supply 51 sends the appropriate drive current to the laser diode 50, through input and output current connections of the laser diode, namely to the anode 54 and from the cathode 55 of the laser diode, by cables having completely covered insulation 54, that advantageously includes the legs and casing of the laser diode mount or legs themselves. These current leads include two auxiliary gated switches S1 and S2, controlled by a gate controller, which could be incorporated within the main controller 52. The enablement of current from the laser diode power supply 51 to the anode 55 of the laser diode, and from the cathode 56 of the laser diode to the ground of the circuit, or to the negative terminal of the laser diode power supply, is thus controlled by the two switches, S1, S2. This ON/OFF control is in addition to the basic level control of the laser current from the laser diode power supply 51 itself, whose output level is controlled by the main controller 52. These two switches S1, S2, which are held in the conducting state (hereinafter “closed”) by control voltages on their gates, are used for additional safety, enabling two additional and independently redundant methods of terminating the current to the laser, which can be implemented either separately or both together, besides the conventional control of the diode current by the controller 52. However, the conventional control of the laser diode current may not always achieve its desired function in the event of a short circuit providing current to the laser diode other than through the laser diode power supply 51. It is under these circumstances, for instance, that the two switches S1, S2, provide the additional safety method of shutting down the laser emission when conditions necessitate such a close down.

An additional safety feature of this switching process for interrupting the laser diode current, arises from the manner in which the switches are powered, relative to the other electronic modules and functions of the system. The operation of these two gated switches makes use of the fact that most infra-red laser diodes typically operate at low voltages, in the region of below 1.5V. This is a significantly lower voltage than that used by most other electronic components associated with the electronic circuitry of the system, being generally based on Si semiconductor technology. Such Si technology devices cannot operate at such a low voltage, and use a higher operating voltage, typically 1.7V, 3.3V, 5V or 12V or others.

The function of the gate controller within or separate from the main controller 52, is to stop lasing by opening at least one of the switches S1, S2, under conditions when the main laser driver controller 52 does not do so when instructed. The gate controller functionality could be incorporated as an additional unit of the main controller 52, but it may be implemented as an additional and separate circuit module (not shown in FIG. 5).

At least one of the two switch gates is arranged to be in the normally non-conducting state when not actively held in the conducting state by application of the required voltage to the switch gate. The laser current is enabled during normal operation by holding the gate in its conducting state by a voltage supplied by the gate controller. When that latching voltage drops, the gate will revert to the open non-conducting state. The switch gates, or more specifically, the gate controller circuit, are driven from the system main power supply (not shown in FIG. 5) by a separate operating voltage V2, higher than the voltage V1 supplied to the main controller 52 or to the laser diode power supply 51, or to any other electronic function in the system. In the event that a physical short circuit occurs, resulting in the application onto the anode lead 54 of the laser diode, of a voltage of more than 1.5V, which is a typical voltage up to which infrared laser diodes operate, the laser diode 50 will turn on and emit a laser beam, even in a situation when the controller 52 is instructing the laser driver to be in its off-state, and the anode switch S1 is being instructed to be non-conducting. The same situation applies if such a circuit malfunction occurs in the laser diode power supply 51, and a current is delivered to the laser even when not instructed by the controller 52 to do so. Since the laser diodes operate at 1.5v or less, and inadvertent application of another voltage present in the circuitry will be higher than 1.5v, the increased current drawn from the main power supply may cause a fall in the main power supply voltage to all of the control functions of the system, or alternatively, a fall to a level which is not high enough to reliably operate the controller 52. Since the gates of the switches are actuated by the controller 52 at a higher voltage than the main controller 52 itself, this fall in voltage will switch the gated switches to their non-conducting state independently of the controller instructions to the laser power supply 51. Bringing either of those switches S1, S2, to their non-conducting state will thus stop the laser diode current, and bring the system to a safe state, regardless of the functional action of any of the other circuit controllers, such as the main controller 50, or electronic safeguard mechanisms of the system.

In conclusion, the use of a higher power supply voltage V2 to the gate controller ensures that in the event of a fault causing a reduction in the voltages supplied overall by the system power supply, the gate controller should be the first circuit to drop out, since it is operated at a higher voltage than the other circuit elements, and will thus cut off the gate holding voltage and hence the power to the laser diode, before and independently of what is happening with the other controller functions.

In a second alternative situation, if the voltage applied to power the main controller 50 drops sufficiently to cause the main controller to malfunction, and therefore not to respond by reducing the unexpected and uncontrolled laser diode current, the feature of making the switch operation through the gate controller 53 dependent on a higher operating voltage than that of the system controller 50 or the laser driver 48, means that the switches will become non-conducting, and hence terminate the laser diode current, regardless of what the system controller or the laser driver are attempting to do.

All the points in the circuit, which could be short circuited to ground or to another live metallic contact within the laser generator enclosure, should be well electrically insulated. This protection is especially important when a C-mount laser diode is used, since such a C-mount has large areas of exposed metallic surfaces being part of the diode conductors, which could be short circuited to ground or to another live metallic contact within the laser generator enclosure, in the event of a mechanical intrusion, or a mechanical fault, such as a loose wire connection becoming free. This is not a trivial task to achieve completely, without having an effect on the cooling requirements of the laser diode.

Example embodiments are provided so that this disclosure will be thorough, and will fully convey the scope to those who are skilled in the art. Numerous specific details are set forth such as examples of specific components, devices, and methods, to provide a thorough understanding of embodiments of the present disclosure. It will be apparent to those skilled in the art that specific details need not be employed, that example embodiments may be embodied in many different forms and that neither should be construed to limit the scope of the disclosure. Furthermore, it is appreciated by persons skilled in the art that the present invention is not limited by what has been particularly shown and described hereinabove. Rather the scope of the present invention includes both combinations and subcombinations of various features described hereinabove as well as variations and modifications thereto which would occur to a person of skill in the art upon reading the above description and which are not in the prior art.

We claim:

1. A laser diode emitting a laser beam for optical wireless power transmission, the laser diode comprising:
a first cladding layer having a first refractive index, and a second cladding layer having a second refractive index, between which there lies an emitting region comprising:
a positively doped layer having a third refractive index, and a negatively doped layer having a fourth refractive index, each of the third and the fourth refractive indices being larger than either of the first and second refractive indices; and
a gain medium layer deposited between the positively doped layer and the negatively doped layer, and having an energy bandgap of between 0.8 eV to 1.2 eV,
wherein the width w, in meters, of the emitting region is within the range:
$$\frac{5 * {10}^{- 27}}{E * {n}_{2}} > \frac{5 * {10}^{- 27}}{E * {n}_{1}} > w > \frac{5 * {10}^{- 28}}{E * {n}_{2}} > \frac{5 * {10}^{- 28}}{E * {n}_{1}}$$
where E is the bandgap of the gain layer measured in Joules, n₁ is the average refractive index of the doped layers, and n₂ is the average refractive index of the cladding layers, and wherein:
the upper limit of w is selected to ensure that in the slow axis, the beam has a spatial multimode form of a required quality, by having at least a first predetermined percentage of its power concentrated in the Hermitian-Gaussian TEM₀₀ mode, and no more than a second predetermined percentage of its power in higher order TEMₙₘ modes having (n+m) greater than a preset number, and
the lower limit of w is selected to ensure that in the slow axis, the beam has sufficient combination of higher order modes so that it produces at least a required level of laser beam output power.

2. A laser diode according to claim 1, wherein the first and second refractive indices may have essentially the same value, and wherein the third and fourth refractive indices may have essentially the same value.

3. A laser diode according to either of the previous claims, wherein the first predetermined percentage is 50%.

4. A laser diode according to either of claims 1 and 2, wherein the second predetermined percentage is 15%.

5. A laser diode according to any of the previous claims, wherein the preset number is 20.

6. A laser diode according to any of the previous claims, wherein the desired level of laser output beam power is 300 mW.

7. A laser diode according to claim 6, wherein the level of laser beam power having a wavelength outside of the range from 1150 nm to 1550 nm is less than 2 mW.

8. A laser diode according to any of the previous claims, wherein the laser diode has a cavity of length L in meters, such that for the range of w of claim 1, the Fresnel Number in the slow axis, w²/λL, is between 0.01 and 20.

9. A laser diode according to any of the previous claims, wherein the laser beam has:
an M² value in the direction of the slow axis of less than 15; and
an M² value in the direction of the fast axis of less than 1.5, and a divergence of the laser beam in the direction of the fast axis of less than 60°.

10. A laser diode according to any of the previous claims, wherein
the mode of the collimated laser beam is such that when imaged by an appropriate optical system to a distance of 10 m. the beam has a single lobe; and
the effective radius r of the focused laser beam thereby created at the 10 m. distance, is given by the expression:
$$20 h * tan ( \frac{6 * {10}^{- 7}}{h} ) < r < \frac{10 w}{2000000 * {h}^{2}}$$
where h is the height of the laser emitter, measured in meters,
w is the width of the emitting region, measured in meters,
r is the effective spot radius, measured in meters, and
the tan function is in radians.

11. A laser diode according to any of the previous claims, wherein the effective radius r of the focused laser beam spot includes 95% of the laser beam power.

12. A laser diode according to any of the previous claims, wherein the laser gain medium layer comprises any of:
a quantum dot gain layer.
a GaInAs composition
a GaAsSb composition
an InPAs composition
an AlAs composition or
a quaternary material.

13. A laser diode according to any of the previous claims, wherein the cladding and doped diode layers have a symmetrical or a near-symmetrical structure relative to the gain medium layer.

14. A system for transmitting laser power from a transmitter to a remote receiver, the system comprising:
a laser diode source comprising a gain medium sandwiched between p- and n-doped layers, and supplied with current from a laser driver;
an optical system for collimating the laser beam emitted from the laser diode source, to produce a spot of illumination on the remote receiver; and
a scanning system for directing the collimated laser beam towards the aperture of a photovoltaic cell on the remote receiver; wherein:
the gain medium of the laser diode is selected so that the laser diode emits a beam at a wavelength λ of between 1150 nm and 1550 nm;
the current supplied by the laser driver to the gain medium is selected such that laser beam has a power of at least 300 mW; and
the laser diode source has an emitter width w of between 15 and 250 μm, such that:
the laser beam is a spatial multimode beam, having at least 50% of its power concentrated in the Hermitian-Gaussian TEM₀₀ mode, and less than 15% of its power in higher order TEMₙₘ modes having (n+m) is greater than 20; and
the laser diode gain medium length is selected such that the laser diode has a Fresnel Number in a slow axis, w²/λL, of between 0.01 and 20, where L is the length of the laser cavity, yielding a beam having:
an M² value in the direction of the slow axis of less than 15;
an M² value in the direction of a fast axis of less than 1.5;
a divergence of the laser beam in the direction of the fast axis of less than 60°;
a single lobed mode of the collimated laser beam, when imaged by the optical system to a distance of 10 m; and
a consequentially focused spot of the laser beam, given by the expression:
$$20 h * tan ( \frac{6 * {10}^{- 7}}{h} ) < r < \frac{10 w}{2000000 * {h}^{2}}$$
where h is the combined height of p- and n-doped layers and the gain medium, measured in meters,
w is the width of the gain medium, measured in meters,
r is an effective radius of the focused spot, and
the tan function is in radians.

15. A system according to claim 14, wherein the bandgap of the gain medium of the laser diode lies within the range of 0.8 eV to 1.2 eV.

16. A system according to either of claims 14 and 15 wherein the laser diode is constructed on a substrate of a III-V or II-VI semiconductor.

17. A system according to any one of claims 14 to 16, wherein the laser diode has a gain medium layer comprising any of a quantum dot structure, a GaInAs composition, a GaAsSb composition, an InPAs composition, an InAlAs composition, or a quaternary material.

18. A system according to any one of claims 14 to 17, wherein the focused spot size has an effective radius r which includes 95% of the power of the beam.

19. A system according to any one of claims 14 to 18, wherein the power of the laser diode emitted at wavelengths outside of the range between 1150 nm and 1550 nm does not exceed 2 mW.

20. A system according to any one of claims 14 to 19, wherein the gain medium is disposed between an n-doped layer and a p-doped layer, having a mean refractive index of n₁, and which are themselves disposed between cladding layers having a refractive index of n₂.

21. A system according to claim 20, wherein the width w of the gain medium is within the ranges given by the expression:
$$\frac{5 * {10}^{- 27}}{E * {n}_{2}} > \frac{5 * {10}^{- 27}}{E * {n}_{1}} > w > \frac{5 * {10}^{- 28}}{E * {n}_{2}} > \frac{5 * {10}^{- 28}}{E * {n}_{1}}$$
where E is the bandgap of the gain medium layer measured in Joules,
n₁ is the mean refractive index of the doped layers, and
n₂ is the mean refractive index of the cladding layers.

22. A system according to any one of claims 14 to 21, wherein the electrical connections for providing current from the laser driver to the laser diode are insulated connections adapted to prevent the likelihood of an inadvertent electrical connection to the laser diode, thereby increasing the safety of the system.

23. A system according to any one of claims 14 to 22, wherein the electrical connections for providing current from the laser driver to the laser diode have at least one gated switch for controlling the flow of current through each of the electrical connections.

24. A system according to claim 23, wherein the gated switches for controlling the flow of current through each of the electrical connections are activated by a gate driver having an operating voltage higher than the operating voltage of other electronic circuits of the system providing control functions to the system.

25. A system according to claim 24, wherein the gate driver is configured to hold each of the gated switches in its conducting state, when the gate driver is instructed to activate the gate.

26. A system according to claim 25, wherein a fall of the operating voltage of the gate driver to a level below the operating voltage of the other electronic circuits of the system providing control functions to the system, causes the gate switches to revert to a non-conducting state.

27. A system according to claim 26, wherein the non-conducting state thus isolates the laser diode from any source of current, even if arising from the inadvertent electrical connection to the laser diode.
